(19) United States
(12) Patent Application Publication
(10) Pub. No.: US 2025/0158582 A1
(43) Pub. Date: May 15, 2025

(54) Bias Control Integrated Circuit

(71) Applicant: Ampleon Netherlands B.V., Nijmegen (NL)

(72) Inventors: Fabien Leroy, Nijmegen (NL); Jerome Mercier, Nijmegen (NL)

(21) Appl. No.: 18/945,390

(22) Filed: Nov. 12, 2024

(30) Foreign Application Priority Data
Nov. 14, 2023 (NL) 2036268

(51) Int. Cl. H03F 3/24

(52) U.S. Cl. CPC H03F 3/245; H03F 2200/451

(57) ABSTRACT

The present disclosure relates to a bias control integrated circuit, and is related to a bias control integrated circuit that is capable of simultaneously providing biasing signals of different polarities and that is capable of being used in time domain duplexing, TDD, systems. The bias control integrated circuit comprises a plurality of identical biasing circuits that each comprise an input node for receiving a digital value, and a DAC for converting the received digital value into an analog biasing signal that lies in between a respective high voltage and a respective low voltage. The output of the DAC forms a first output node of the biasing circuit. The biasing circuit further comprises a second output node, and a switching unit connected to the first output node and second output node and configured to output, at the second output node and as a switched analog biasing signal.

### CROSS-REFERENCE TO RELATED APPLICATION

The present application is a non-provisional patent application claiming priority to Netherlands Patent Application No. NL 2036268, filed Nov. 14, 2023, the contents of which are hereby incorporated by reference.

### FIELD OF THE DISCLOSURE

The present disclosure relates to a bias control integrated circuit. In particular, the present disclosure is related to a bias control integrated circuit that is capable of simultaneously providing biasing signals of different polarities and that is capable of being used in time domain duplexing, TDD, systems. The present disclosure is further related to a biasing circuit used in such bias control integrated circuit and to a radiofrequency, RF, power amplifier module comprising such a bias control integrated circuit.

### BACKGROUND

Typically, bias control integrated circuits comprise a plurality of identical biasing circuits integrated on a semiconductor die. Each biasing circuit generates a separate biasing signal to be provided to an amplifying stage. For example, each biasing circuit can be configured to generate a respective gate biasing signal for a multi-stage amplifier comprising a plurality of field-effect transistors.

The bias control integrated circuit can be part of a power amplifier module. Such modules comprise a substrate on which the bias control integrated circuit is mounted together with one or more semiconductor dies on which the power transistors of the power amplifier are integrated.

Power amplifier modules are generally designed to be used in various telecommunications schemes. For example, power amplifier modules can be designed to be operable in time division duplexing systems in which the power amplifier modules may (e.g., need) to be able to quickly switch between an on-state and an off-state. Additionally, these same power amplifier modules may be designed to also be operable in frequency division multiplexing, in which the power amplifier modules can be in the on-state for relatively long periods of time.

Recently, power amplifier modules have been developed in which power transistors are used that are based on different semiconductor technologies. For example, power amplifier modules using both Gallium Nitride based field-effect transistors and Silicon based laterally diffused metal-oxide-semiconductor transistors have been disclosed. Hereinafter, such power amplifier modules are referred to as hybrid power amplifier modules.

An example of a hybrid power amplifier module is schematically illustrated in FIG. 1. Here, power amplifier module 100 comprises a substrate 11 on which a bias control integrated circuit, IC, 13, a first power amplifier 30 of a first semiconductor technology, and a second power amplifier 40 of a second semiconductor technology different from the first semiconductor technology, are arranged. Power amplifiers 30, 40 are provided as separate semiconductor dies mounted on substrate 11. In case the semiconductor technology of a power amplifier, for example, power amplifier 30, is identical to that of bias control IC 13, the power amplifier and bias control IC can be realized as a single semiconductor die.

Power amplifier module 100 receives a radiofrequency, RF, input signal RF_in, and a signal D that represents the bias settings to be used for power amplifiers 30, 40. Bias IC 13 comprises an arithmetic unit 21 that determines input signals to be provided to biasing circuits 22, 23 in dependence of a measured temperature T. In this way, changes in performance of power amplifiers 30, 40 as a function of temperature, in particular the ambient temperature, can be compensated for.

Biasing circuits 22, 23 each provide a biasing signal, in dependence of measured temperature T and signal D, to a respective power amplifier 30, 40. The final stage of power amplifier module 100, e.g., power amplifier 40, provides its output signal RF_out to a load ZL external to power amplifier module 100. Furthermore, power amplifiers 30, 40 are each provided with a separate supply voltage Vdd1, Vdd2. For example, power amplifiers 30, 40 can be realized using field-effect transistors. In this case, supply voltages Vdd1 and Vdd2 are used for biasing the drain terminals of the field-effect transistors, whereas biasing circuits 22, 23 bias the gate terminals. Supply voltages are typically provided using sources external to power amplifier module 100.

Hybrid power amplifier modules may use (e.g., require) the bias control IC to output biasing signals of different polarities. For example, Gallium Nitride field-effect transistors require a gate voltage to be in the range between −10V and 0V, whereas Silicon laterally diffused metal-oxide-semiconductor transistors require the gate voltage to be in the range between 0V and 5V. Using outputting biasing signals of different polarities, as well as that the same bias control IC can be used for TDD applications, is not met by currently known bias control ICs.

It is therefore an object of the present disclosure to provide a bias control integrated circuit that is capable of (e.g., simultaneously) outputting biasing signals of different polarities and that can be used in TDD systems.

### SUMMARY

In one implementation, a bias control integrated circuit for providing a plurality of biasing signals, comprising a semiconductor die on which a plurality of biasing circuits is integrated is provided. Each biasing circuit being independently operable in a mode among a plurality of modes. Each biasing circuit comprises a reference high node (An; A1, A2) of which a voltage during operation is configured to be equal to a respective high voltage among a plurality of high voltages corresponding to the plurality of modes, a reference low node (Bn; B1; B2) of which a voltage during operation is configured to be equal to a respective low voltage among a plurality of low voltages corresponding to the plurality of modes, an input node (Sn) for receiving a digital value, a digital-to-analog converter, DAC, (210) for converting the received digital value into an analog biasing signal that lies in between the respective high voltage and the respective low voltage, wherein an output of the DAC forms a first output node (Vgn, Vg1) of the biasing circuit, a second output node (Vgn,s, Vg1,s), and a switching unit (220) connected to the first output node and second output node and configured to output, at the second output node and as a switched analog biasing signal, either the analog biasing signal output by the DAC or the respective low voltage in dependence of a switching signal (TDD).

In an example implementation of the bias control integrated circuit, a polarity of at least one high voltage is different from the polarity of at least one other high voltage and/or a polarity of at least one low voltage is different from the polarity of at least one other low voltage.

In an example implementation of the bias control integrated circuit, the switching unit of each biasing circuit comprises a first switching unit (Q1) arranged in between the first output node and the second output node of the biasing circuit, a second switching unit (Q2) arranged in between the second output node and a reference node that is electrically connected to the reference low node, and a switch controller (2201) configured for controlling the first switching unit and the second switching unit in dependence of the switching signal. The switch controller is configured to control, in response to the switching signal having a first logical value, the first switching unit to provide a low ohmic connection between the first output node and the second output node, and the second switching unit to provide a high ohmic connection between the second output node and the reference node. The switch controller is configured to control, in response to the switching signal having a second logical value different from the first logical value, the first switching unit to provide a high ohmic connection between the first output node and the second output node, and the second switching unit to provide a low ohmic connection between the second output node and the reference node.

In an example implementation of the bias control integrated circuit, the plurality of modes comprise a first mode in which the voltage at the reference high node during operation is configured to be equal to a first high voltage and the voltage at the reference low node during operation is configured to be equal to a first low voltage, and a second mode during which the voltage at the reference high node during operation is configured to be equal to a second high voltage and the voltage at the reference low node during operation is configured to be equal to a second low voltage.

In an example implementation of the bias control integrated circuit, the reference high node and reference low node of each biasing circuit among the plurality of biasing circuits are each formed by a terminal, and wherein, for the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage and/or the supply of the low voltage are preferably arranged off the semiconductor die.

In an example implementation of the bias control integrated circuit, a reference voltage setting unit (405) is configured to set, in dependence of a mode signal for a given biasing circuit intended for setting that biasing circuit to operate in a given mode among the plurality of modes, the voltage at the reference high node of that biasing circuit to a high voltage among the plurality of high voltages that corresponds to the given mode, and the voltage at the reference low node of that biasing circuit to a low voltage among the plurality of low voltages that corresponds to the given mode.

In an example implementation of the bias control integrated circuit, the semiconductor die comprises a plurality of common high nodes of which the voltages during operation equal the plurality of high voltages, and a plurality of common low nodes of which the voltages during operation equal the plurality of low voltages, wherein the reference voltage setting unit is connected to the plurality of common high nodes and to the plurality of common low nodes.

In an example implementation of the bias control integrated circuit, the common high nodes of the plurality of common high nodes are configured to be electrically connected to supplies of the high voltages, and/or the common low nodes of the plurality of common low nodes are configured to be electrically connected to supplies of the low voltages, wherein the supplies of the high voltages and/or the supplies of the low voltages are preferably arranged off the semiconductor die, and wherein the reference voltage setting unit is configured to set each biasing circuit among the plurality of biasing circuits to operate in a given mode among the plurality of modes in dependence of a mode signal that indicates a desired mode for each of the biasing circuits.

In an example implementation of the bias control integrated circuit, the semiconductor die comprises a controller (302) that is configured for determining and providing a respective digital value for each biasing circuit, wherein the controller is configured for receiving one or more input signals and for determining the respective digital values in dependence of the one or more input signals, and wherein the controller is configured for receiving a separate input signal for each biasing circuit.

In an example implementation of the bias control integrated circuit, the controller is configured for generating the respective digital value for each biasing circuit in dependence of a temperature measured by a temperature sensor and the one or more input signals.

In an example implementation of the bias control integrated circuit, the temperature sensor is arranged on the semiconductor die.

In an example implementation of the bias control integrated circuit, the controller comprises a lookup table (302B) holding a respective digital value for a plurality of temperatures and a plurality of possible values of the one or more input signals, and an arithmetic unit (302A) configured to calculate or determine the digital value to be outputted to each biasing circuit based on the measured temperature, the digital value or values held in the lookup table that correspond to the measured temperature for the values of the one or more input signals.

In an example implementation of the bias control integrated circuit, the arithmetic unit is configured to determine the digital value to be outputted to each biasing circuit using interpolation based on two or more digital values held in the lookup table that correspond to temperatures that are higher and lower than the measured temperature, wherein the lookup table holds respective digital values for a plurality of temperatures for each biasing circuit separately.

In another implementation, an RF power amplifier module (500; 600; 700; 800), comprising a plurality of power amplifiers (10, 20) is provided. Each power amplifier having one or more power transistors of a technology that is different from the technology of the power transistors of at least one other power amplifier among the plurality of power amplifiers. The RF power amplifier module also includes the bias control integrated circuit (400) for providing a plurality of biasing signals. The circuit (400) comprises a semiconductor die on which a plurality of biasing circuits is integrated. Each biasing circuit being independently operable in a mode among a plurality of modes. Each biasing circuit comprises a reference high node (An; A1, A2) of which a voltage during operation is configured to be equal to a respective high voltage among a plurality of high voltages corresponding to the plurality of modes, a reference low node (Bn; B1; B2) of which a voltage during operation is configured to be equal to a respective low voltage among a plurality of low voltages corresponding to the plurality of modes, an input node (Sn) for receiving a digital value, a digital-to-analog converter, DAC, (210) for converting the received digital value into an analog biasing signal that lies in between the respective high voltage and the respective low voltage, wherein an output of the DAC forms a first output node (Vgn, Vg1) of the biasing circuit, a second output node (Vgn,s, Vg1,s), and a switching unit (220) connected to the first output node and second output node and configured to output, at the second output node and as a switched analog biasing signal, either the analog biasing signal output by the DAC or the respective low voltage in dependence of a switching signal (TDD). Each biasing circuit is configured to provide its analog biasing signal or its switched analog biasing signal to a controlling input of a respective power transistor of a power amplifier among the plurality of power amplifier. The biasing circuit(s) of the bias control integrated circuit that is/are configured to bias the power transistor(s) of a given power amplifier among the plurality of power amplifiers are configured to operate in a different mode than the biasing circuit(s) of the bias control integrated circuit that is/are configured to bias the power transistor(s) of a different power amplifier among the plurality of power amplifiers.

In one implementation of the power amplifier module, the one or more power transistors of a power amplifier among the plurality of power amplifiers are based on a same semiconductor material that is different from a semiconductor material on which the one or more power transistors of a different power amplifier among the plurality of power amplifiers are based. The one or more power transistors of a first power amplifier among the plurality of power amplifiers are based on Gallium Nitride, and for example each comprise a Gallium Nitride based field-effect transistor. The one or more power transistors of a second power amplifier among the plurality of power amplifiers are based on Silicon, and for example each comprise a Silicon laterally diffused metal-oxide-semiconductor transistor.

In an example implementation of the power amplifier module, a first substrate (501), such as a laminate substrate, wherein the one or more power transistors of each power amplifier are provided as one or more semiconductor dies mounted on the first substrate, wherein the first substrate comprises one or more terminals for electrically connecting the power amplifier module to a second substrate on which the power amplifier module is or is to be mounted, wherein the power amplifier module is packaged as a land grid array, LGA, package, or a no-lead package, such as a quad flat no-lead package, QFN.

In an example implementation of the power amplifier module, the reference high node and reference low node of each biasing circuit among the plurality of biasing circuits are each formed by a terminal. For the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage and/or the supply of the low voltage are preferably arranged off the semiconductor die, wherein the off-die supplies for the high voltages of the plurality of high voltages and wherein the off-die supplies for the low voltages of the plurality of low voltages are realized using one or more voltage generating units arranged on the first substrate.

In an example implementation of the power amplifier module, the reference high node and reference low node of each biasing circuit among the plurality of biasing circuits are each formed by a terminal, and wherein, for the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage and/or the supply of the low voltage are preferably arranged off the semiconductor die, the power amplifier module comprising a plurality of terminals configured to be connected to supplies of the high voltages and to supplies of the low voltages external to the power amplifier module, wherein the reference high node and reference low node of each biasing circuit are electrically connected to a respective terminal among the plurality of terminals of the power amplifier module.

In another implementation, a biasing control integrated circuit is provided. The circuit comprising a biasing circuit (200) comprising a reference high node (An) of which a voltage during operation is configured to be equal to a respective high voltage among a plurality of high voltages corresponding to a plurality of modes, a reference low node (Bn) of which a voltage during operation is configured to be equal to a respective low voltage among a plurality of low voltages corresponding to the plurality of modes, an input node (Sn) for receiving a digital value, a digital-to-analog converter, DAC, (210) for converting the received digital value into an analog biasing signal that lies in between the respective high voltage and the respective low voltage, wherein an output of the DAC forms a first output node (Vgn) of the biasing circuit, a second output node (Vgn,s), and a switching unit (220) connected to the first output node and second output node and configured to output, at the second output node and as a switched analog biasing signal, either the analog biasing signal output by the DAC or the respective low voltage in dependence of a switching signal, and a reference voltage setting unit (405), The reference voltage setting unit configured to set, in dependence of a mode signal for the biasing circuit intended for setting the biasing circuit to operate in a given mode among the plurality of modes. The modes including the voltage at the reference high node of the biasing circuit to a high voltage among the plurality of high voltages that corresponds to the given mode, and the voltage at the reference low node of the biasing circuit to a low voltage among the plurality of low voltages that corresponds to the given mode. A polarity of at least one high voltage is different from the polarity of at least one other high voltage and/or wherein a polarity of at least one low voltage is different from the polarity of at least one other low voltage.

In another implementation, a biasing control integrated circuit is provided. The circuit comprising a biasing circuit (200) comprising a reference high node (An) of which a voltage during operation is configured to be equal to a respective high voltage among a plurality of high voltages corresponding to a plurality of modes, a reference low node (Bn) of which a voltage during operation is configured to be equal to a respective low voltage among a plurality of low voltages corresponding to the plurality of modes, an input node (Sn) for receiving a digital value, a digital-to-analog converter, DAC, (210) for converting the received digital value into an analog biasing signal that lies in between the respective high voltage and the respective low voltage, wherein an output of the DAC forms a first output node (Vgn) of the biasing circuit, a second output node (Vgn,s), and a switching unit (220) connected to the first output node and second output node and configured to output, at the second output node and as a switched analog biasing signal, either the analog biasing signal output by the DAC or the respective low voltage in dependence of a switching signal, and wherein the reference high node and reference low node of the biasing circuit are each formed by a terminal, and wherein, for the purpose of operating the biasing circuit in a respective mode, the reference high node and reference low node of the biasing circuit are configured to be connected a supply of the high voltage and to a supply of the low voltage that correspond to the mode the biasing circuit operates or should operate in, respectively, wherein a polarity of at least one high voltage is different from the polarity of at least one other high voltage and/or wherein a polarity of at least one low voltage is different from the polarity of at least one other low voltage.

### BRIEF DESCRIPTION OF THE FIGURES

The above, as well as additional, features will be better understood through the following illustrative and non-limiting detailed description of example embodiments, with reference to the appended drawings.

FIG. 1 illustrates a (e.g., known) power amplifier module;

FIG. 2 schematically illustrates a biasing circuit in accordance with the present disclosure;

FIG. 3 illustrates an implementation of the biasing circuit of FIG. 2;

FIG. 4 illustrates an embodiment of a bias control integrated circuit in accordance with the present disclosure;

FIG. 5 illustrates a first embodiment of a power amplifier module in accordance with the present disclosure;

FIG. 6 illustrates a second embodiment of a power amplifier module in accordance with the present disclosure;

FIG. 7 illustrates a third embodiment of a power amplifier module in accordance with the present disclosure; and

FIG. 8 illustrates a fourth embodiment of a power amplifier module in accordance with the present disclosure.

All the figures are schematic, not necessarily to scale, and generally only show parts which (e.g., are necessary to) elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

It is an object of the present disclosure to provide a bias control integrated circuit that is capable of (e.g., simultaneously) outputting biasing signals of different polarities and that can be used in TDD systems.

According to the present disclosure, this object is achieved using the bias control integrated circuit for providing a plurality of biasing signals (e.g., as defined in claim 1). This bias control integrated circuit comprises a semiconductor die on which a plurality of preferably identical biasing circuits is integrated. Each biasing circuit is independently operable in a mode among a plurality of modes. The mode in which each biasing circuit operates can be individually configured and/or set. In some embodiments, the mode in which each biasing circuit operates can be switched. For example, the bias control integrated circuit may comprise a digital control register. In other embodiments, the mode in which each biasing circuit operates is determined by the way in which the biasing circuit is connected, for example using bondwires.

According to the present disclosure, each biasing circuit comprises a reference high node of which a voltage during operation is configured to be equal to a respective high voltage among a plurality of high voltages corresponding to the plurality of modes. Each biasing circuit further comprises a reference low node of which a voltage during operation is configured to be equal to a respective low voltage among a plurality of low voltages corresponding to the plurality of modes.

For example, the bias control integrated circuit comprises six biasing circuits. The voltage at the reference high node and the voltage at the reference low node for a given biasing circuit may be configured in accordance with the table below.

| | Voltage at | Voltage at | |
|---|---|---|---|
| Biasing circuit | reference | reference | |
| no. | high node | low node | Mode |
| 1 | 5 | 0 | 1 |
| 2 | 2 | −4 | 2 |
| 3 | 5 | −2.5 | 3 |
| 4 | 0 | −10 | 4 |
| 5 | 5 | 0 | 1 |
| 6 | 5 | −2.5 | 3 |

Each biasing circuit further comprises an input node for receiving a digital value. This digital value is representative of the biasing signal to be provided by the biasing circuit. A digital-to-analog converter, DAC, is provided in each biasing circuit for converting the received digital value into an analog biasing signal that lies in between the voltage at the reference high node and the voltage at the reference low node. The output of the DAC forms a first output node of the biasing circuit.

Each biasing circuit further comprises a second output node, and a switching unit connected to the first output node and second output node and configured to output, at the second output node and as a switched analog biasing signal, either the analog biasing signal output by the DAC or the respective low voltage in dependence of a switching signal.

The first output node can be used for applications where switching times used (e.g., required) for switching the transistors of power amplifiers on and/or off are less important and/or where switching off during operation is not used (e.g., required). The second output node can be used for applications where such switching times are important, such as for TDD applications. Additionally, or alternatively, switching unit can be configured to be operable in a first mode, in which mode the switching unit outputs, at the second output node and as a switched analog biasing signal, either the analog biasing signal output by the DAC or the respective low voltage in dependence of a switching signal, and/or operable in a second mode, in which mode the switching unit outputs, at the second output node, the analog biasing signal output by the DAC.

A polarity of at least one high voltage may be different from the polarity of at least one other high voltage and/or a polarity of at least one low voltage may be different from the polarity of at least one other low voltage.

The switching unit of each biasing circuit may comprise a first switching unit arranged in between the first output node and the second output node of the biasing circuit, a second switching unit arranged in between the second output node and a reference node that is electrically connected to the reference low node, and a switch controller configured for controlling the first switching unit and the second switching unit in dependence of the switching signal.

For example, the switch controller can be configured to control, in response to the switching signal having a first logical value, the first switching unit to provide a low ohmic connection between the first output node and the second output node, and the second switching unit to provide a high ohmic connection between the second output node and the reference node. Additionally, the switch controller can be configured to control, in response to the switching signal having a second logical value different from the first logical value, the first switching unit to provide a high ohmic connection between the first output node and the second output node, and the second switching unit to provide a low ohmic connection between the second output node and the reference node. For example, the first logical value may represent a logical high value and the second logical value may represent a logical low value. When the switching signal has the first logical value, the voltage at the second output node may be (e.g., substantially) identical to the voltage at the first output node, whereas when the switching signal has the second logical value, the voltage at the second output node may be identical to the voltage at the reference node of the switching unit, which is generally equal or substantially equal to the respective low voltage.

The present disclosure is not limited to any number of modes. However, the plurality of modes may comprise a first mode in which the voltage at the reference high node during operation is configured to be equal to a first high voltage and the voltage at the reference low node during operation is configured to be equal to a first low voltage, and a second mode in which the voltage at the reference high node during operation is configured to be equal to a second high voltage and the voltage at the reference low node during operation is configured to be equal to a second low voltage. Using two different modes allows the bias control integrated circuit to be used for biasing a hybrid power amplifier that uses two different semiconductor technologies for realizing the power amplifiers.

The reference high node and reference low node of each biasing circuit among the plurality of biasing circuits can each be formed by a terminal. For the purpose of operating a given biasing circuit in a respective mode, the reference high node and reference low node of that biasing circuit can be configured to be connected to a supply of the high voltage and to a supply of the low voltage that correspond to the mode that biasing circuit operates or should operate in, respectively. The supply of the high voltage and/or the supply of the low voltage can be arranged off the semiconductor die.

The terminal can be formed using a conductive patch or pad and/or may refer to a particular node in an electrical network. This patch or pad can be arranged for making an electrical connection to a substrate on which the bias control integrated circuit is mounted. For example, for a two-mode biasing control integrated circuit, the reference high node of the first biasing circuit may comprise and/or be formed by a bondpad that is connected, using a bondwire, to a terminal on a substrate on which the bias control integrated circuit is mounted, wherein the terminal provides a 5V voltage. The reference high node of the second biasing circuit may comprise and/or be formed by a bondpad that is connected, using a bondwire, to a terminal on the substrate that provides a 10V voltage.

Alternatively, the bias control integrated circuit may comprise a reference voltage setting unit configured to set, in dependence of a mode signal for a given biasing circuit intended for setting that biasing circuit to operate in a given mode among the plurality of modes, the voltage at the reference high node of that biasing circuit to a high voltage among the plurality of high voltages that corresponds to the given mode, and the voltage at the reference low node of the biasing circuit to a low voltage among the plurality of low voltages that corresponds to the given mode.

The reference voltage setting unit can be connected to supplies for all reference high voltages and reference low voltages. For example, the semiconductor die may comprise a plurality of common high nodes of which the voltages during operation equal the plurality of high voltages and a plurality of common low nodes of which the voltages during operation equal the plurality of low voltages. The reference voltage setting unit may be connected to the plurality of common high nodes and to the plurality of common low nodes. The plurality of common high nodes can be configured to be electrically connected to supplies of the high voltages, and/or the common low nodes can be configured to be electrically connected to supplies of the low voltages. The supplies of the high voltages and/or the supplies of the low voltages can be arranged off the semiconductor die.

The reference voltage setting unit can be configured to set each biasing circuit among the plurality of biasing circuits to operate in a given mode among the plurality of modes in dependence of a single mode signal that indicates a desired mode for each of the biasing circuits. For example, the mode signal to be provided to the reference voltage setting unit may be a digital signal. This mode signal may comprise biasing information for one or all biasing circuit(s).

Preferably, a single reference voltage setting unit is used for setting the high and low voltages for each biasing circuit. Alternatively, multiple reference voltage setting units can be used, for example one for each biasing circuit. In this latter case, each biasing circuit is connected to the common high nodes and the common low nodes. Furthermore, the use of common high nodes and common low nodes in this case enables a single connection to be used to sources of the low and high voltages without having to make separate connections to each reference voltage setting unit.

The semiconductor die may comprise a controller that is configured for determining and providing a respective digital value for each biasing circuit. Information regarding a desired biasing level of the power amplifiers or power transistors connected to the bias control integrated circuit may be stored in a memory inside the bias control integrated circuit, for example in a memory of the controller. This information may for example be the various digital values to be provided to each biasing circuit. Alternatively, the controller can be configured for receiving one or more input signals and for determining the respective digital values in dependence of the one or more input signals. In this case, the information on the basis of which the digital values are to be generated comes from outside the bias control integrated circuit. In this latter case, it is preferred if the controller is configured for receiving a separate input signal for each biasing circuit. However, these separate signals can be part of a common input signal.

The controller can be configured for generating the respective digital value for each biasing circuit in dependence of a temperature measured by the temperature sensor and the one or more input signals. This temperature sensor may be arranged on the semiconductor die. Alternatively, information about the temperature may be provided from one or more power amplifiers that the bias control integrated circuit biases. In a particular embodiment, each power amplifier, or the one or more power transistors of such power amplifier, each provide a respective temperature to the bias control integrated circuit. In this case, the biasing signal to be provided to a power amplifier or one or more power transistors thereof can be individually determined by the controller based on the temperature(s) from that power amplifier or the one or more power transistors thereof.

The memory may comprise a lookup table holding a respective digital value for a plurality of temperatures, and an arithmetic unit configured to calculate or determine the digital value to be output to each biasing circuit based on the measured temperature, the digital value or values held in the lookup table that correspond to the measured temperature for the values of the one or more input signals.

An example of a lookup table is shown below. In this example, the entries for only one biasing circuit are provided. The actual lookup table may comprise information for each biasing circuit.

| | Measured | Digital value |
|---|---|---|
| Input signal | temperature | to be outputted |
| Value #1 for biasing circuit #1 | T1 | Output value #1 |
| Value #1 for biasing circuit #1 | T2 | Output value #2 |
| Value #1 for biasing circuit #1 | T3 | Output value #3 |
| Value #2 for biasing circuit #1 | T1 | Output value #4 |
| Value #2 for biasing circuit #1 | T2 | Output value #5 |
| Value #2 for biasing circuit #1 | T3 | Output value #6 |

If value #1 is provided to the controller, and the arithmetic unit determines that the temperature equals T2, it will determine that Output value #2 should be output to biasing circuit #1. It may happen that the measured temperature does not exactly correspond to a stored temperature. To address this problem, the arithmetic unit can be configured to determine the digital value to be outputted to each biasing circuit using interpolation based on two or more digital values held in the lookup table that correspond to temperatures that are higher and lower than the measured temperature. Referring to the example above, if value #1 is provided to the controller and the measured temperature equals T4, wherein T1<T4<T2, the value to be outputted to biasing circuit #1 is calculated or determined to be between Output value #1 and Output value #2. It is preferred if the lookup table may hold respective digital values for a plurality of temperatures for each biasing circuit separately.

The controller may also be configured to output a digital value to each biasing circuit independent from an input signal. For example, the controller can be configured to ensure a fixed biasing of the power amplifiers or the power transistors thereof. The actual values outputted to the biasing circuit(s) may however change to account for temperature variations.

According to a further aspect, the present disclosure provides a power amplifier module that comprises a plurality of power amplifiers, each power amplifier having one or more power transistors of a technology that is different from the technology of the power transistors of at least one other power amplifier among the plurality of power amplifiers. The power amplifier module further comprises the bias control integrated circuit as described above, wherein each biasing circuit is configured to provide its analog biasing signal or its switched analog biasing signal to a controlling input of a respective power transistor of a power amplifier among the plurality of power amplifiers.

The biasing circuit(s) of the bias control integrated circuit that is/are configured to bias the power transistor(s) of a given power amplifier among the plurality of power amplifiers are configured to operate in a different mode than the biasing circuit(s) of the bias control integrated circuit that is/are configured to bias the power transistor(s) of a different power amplifier among the plurality of power amplifiers.

The one or more power transistors of a power amplifier among the plurality of power amplifiers can be based on a same semiconductor material that is different from a semiconductor material on which the one or more power transistors of a different power amplifier among the plurality of power amplifiers are based. These types of power amplifier modules are referred to as hybrid power amplifier modules. For example, one or more power transistors of a first power amplifier among the plurality of power amplifiers can be based on Gallium Nitride, and for example each comprise a Gallium Nitride based field-effect transistor, and the one or more power transistors of a second power amplifier among the plurality of power amplifiers can be based on Silicon, and for example each comprise a Silicon laterally diffused metal-oxide-semiconductor transistor.

The power amplifier module may further comprise a first substrate, such as a laminate substrate, wherein the one or more power transistors of each power amplifier are provided as one or more semiconductor dies mounted on the first substrate. The first substrate may comprise one or more terminals for electrically connecting the power amplifier module to a second substrate on which the power amplifier module is or is to be mounted. As an example, the power amplifier module can be packaged as a land grid array, LGA, package, or a no-lead package, such as a quad flat no-lead package, QFN. The bias control integrated circuit, and the one or more semiconductor dies on which the power transistors of the power amplifiers are realized, can be mounted to the first substrate using known die placement techniques, such as die bonding or flip-chip bonding.

In so far as high voltage supplies and low voltage supplies are used that are arranged off the semiconductor die of the bias control integrated circuit, the off-die supplies for the high voltages and the off-die supplies for the low voltages can be realized using one or more voltage generating units arranged on the first substrate. Alternatively, the high voltage supplies and low voltage supplies are arranged outside of the power amplifier module. In this latter case, the power amplifier module may comprise a plurality of terminals configured to be connected to supplies of the high voltages and to supplies of the low voltages external to the power amplifier module, wherein the reference high node and reference low node of each biasing circuit are electrically connected to a respective terminal among the plurality of terminals of the power amplifier module.

According to a further aspect, the present disclosure provides a biasing circuit that is configured as the biasing circuits of the bias control integrated circuit described above.

Next, the present disclosure will be described referring to the appended drawings, wherein the same reference signs will be used to refer to the same or similar components.

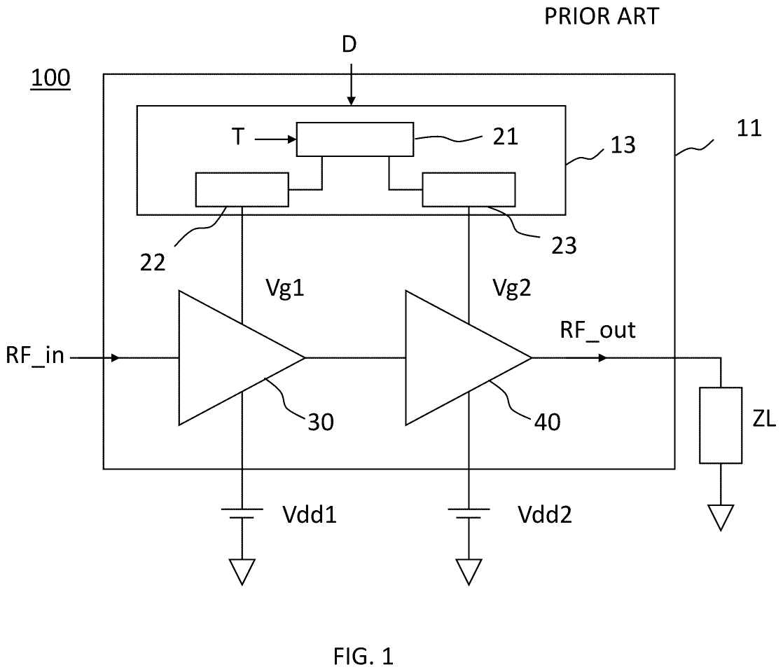

FIG. 1 illustrates a (e.g., known) power amplifier module.

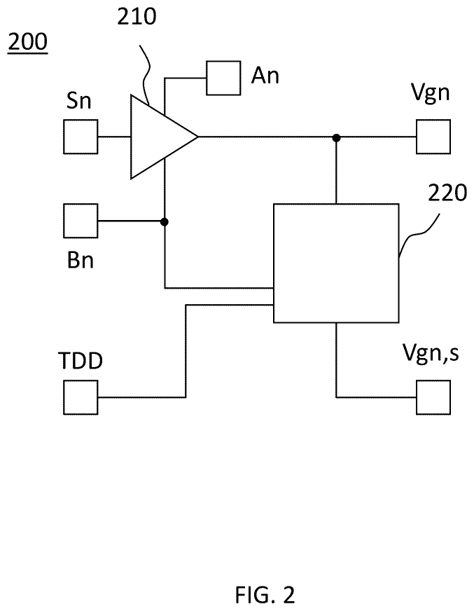

FIG. 2 schematically illustrates a biasing circuit in accordance with the present disclosure.

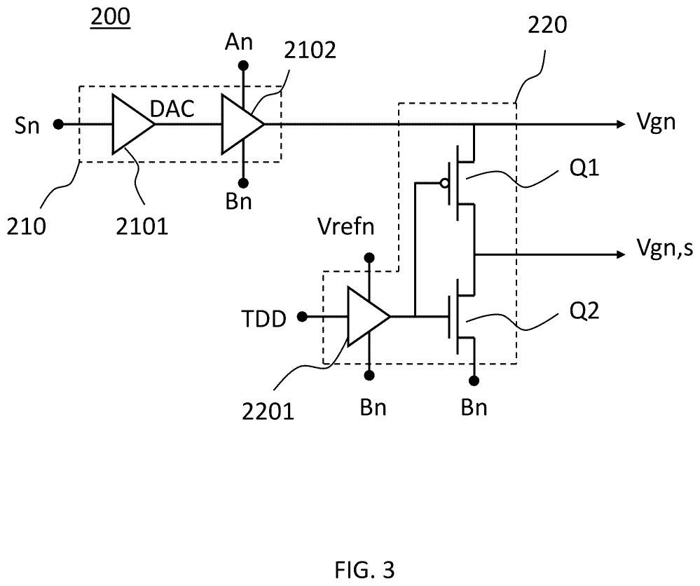

FIG. 3 illustrates an implementation of the biasing circuit of FIG. 2.

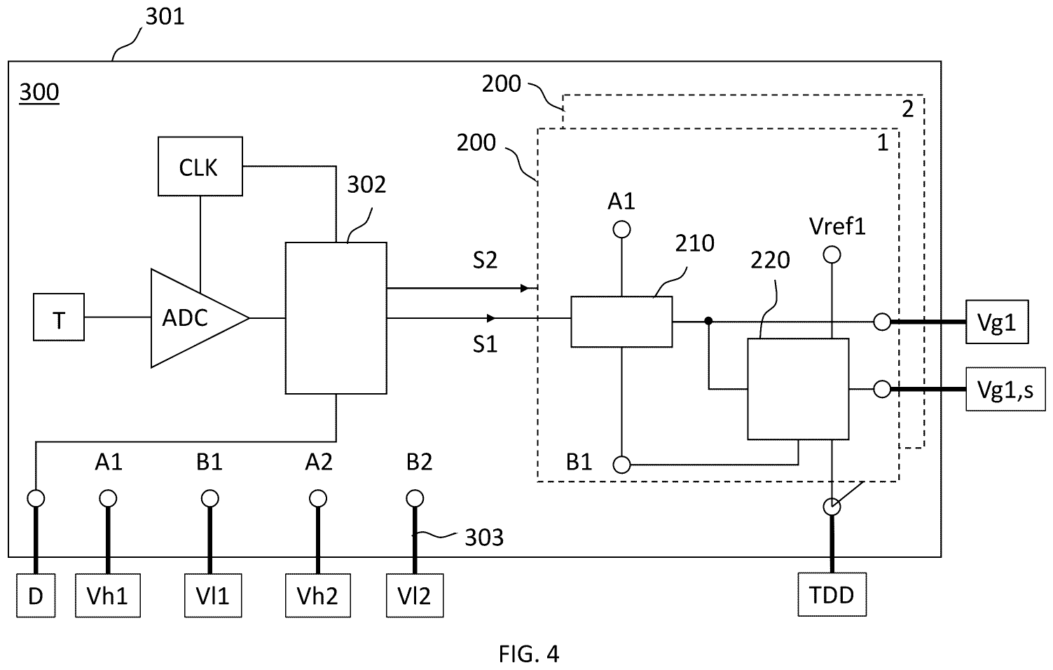

FIG. 4 illustrates an embodiment of a bias control integrated circuit in accordance with the present disclosure.

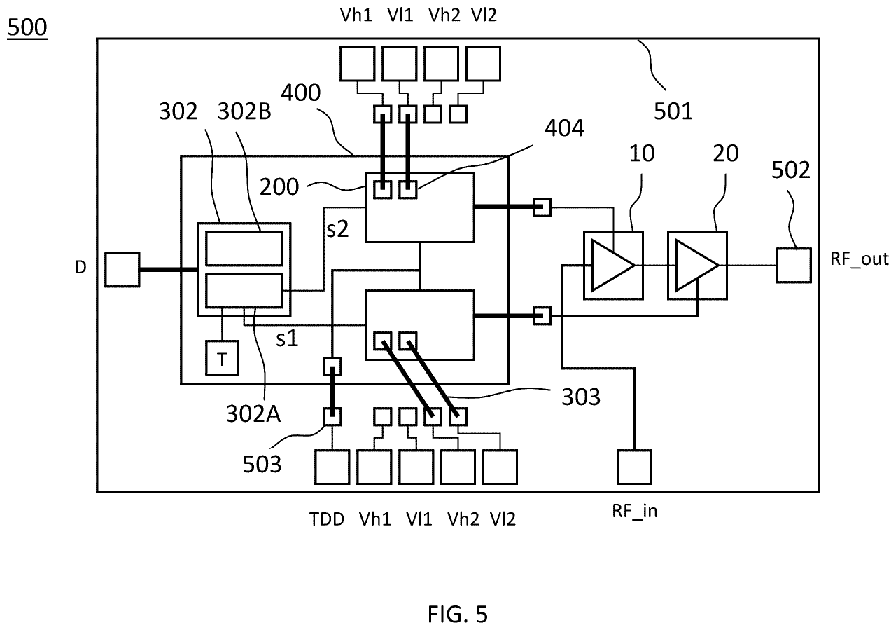

FIG. 5 illustrates a first embodiment of a power amplifier module in accordance with the present disclosure.

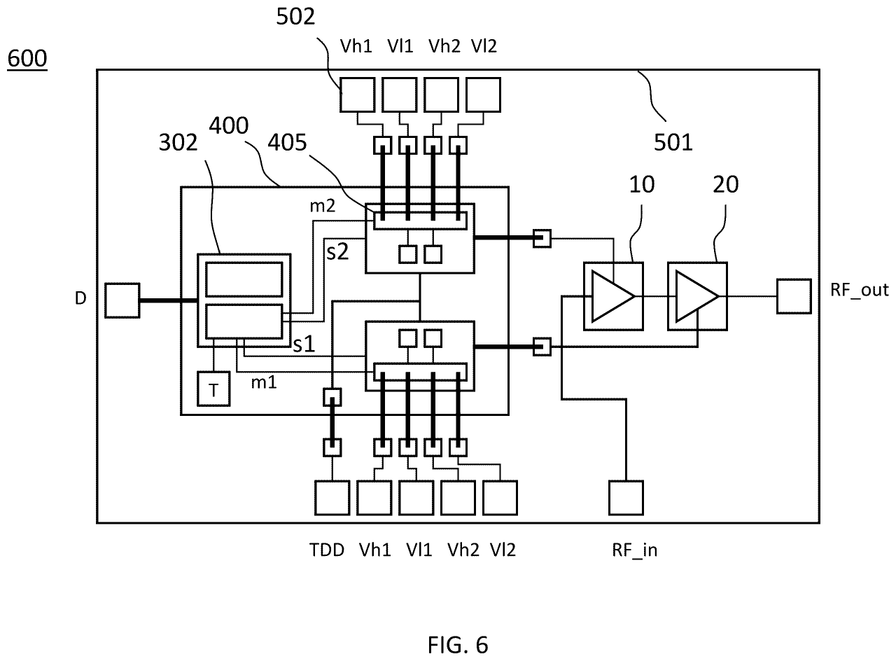

FIG. 6 illustrates a second embodiment of a power amplifier module in accordance with the present disclosure.

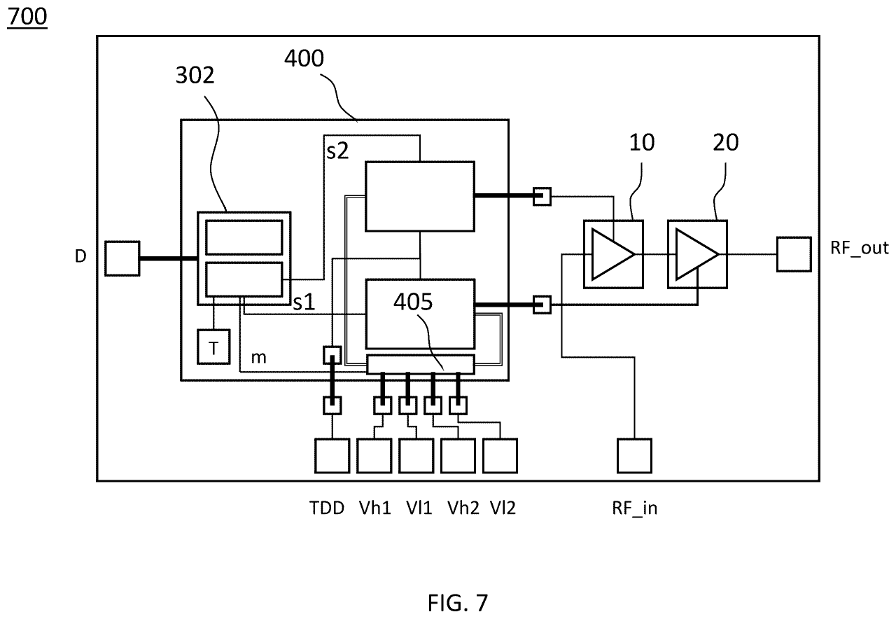

FIG. 7 illustrates a third embodiment of a power amplifier module in accordance with the present disclosure.

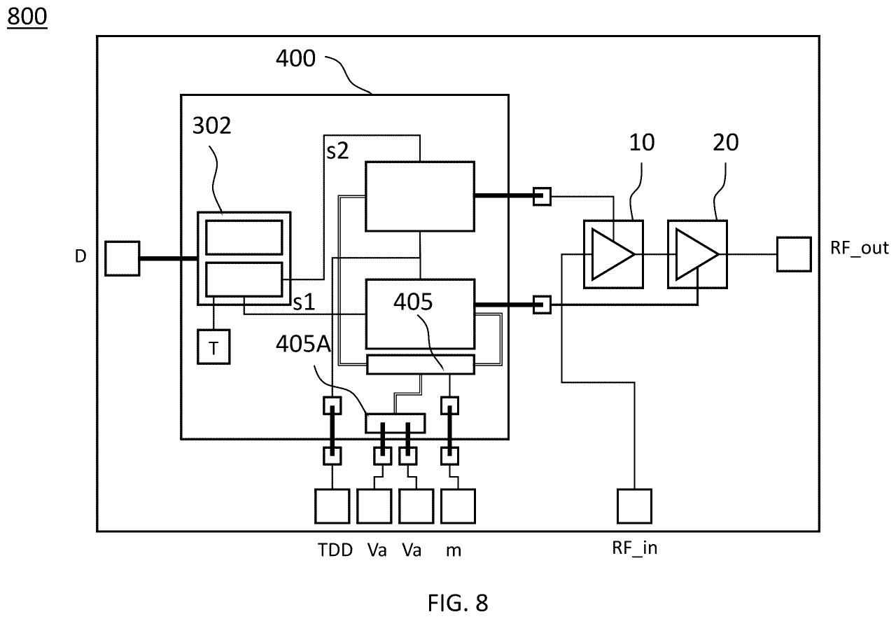

FIG. 8 illustrates a fourth embodiment of a power amplifier module in accordance with the present disclosure.

Turning to the figures, FIG. 2 schematically illustrates a biasing circuit 200 in accordance with the present disclosure. It comprises an input node for receiving a digital value Sn. Hereinafter, a node will be referred to using the reference sign for the signal at that node. For example, node Sn receives the digital value Sn.

Biasing circuit 200 further comprises a reference high node An and a reference low node Bn. Digital-to-analog converter, DAC, 210, converts digital value Sn into an analog biasing signal Vgn that lies in between high voltage An and low voltage Bn. Furthermore, analog biasing signal Vgn is provided at node Vgn, which functions as a first output node of biasing circuit 200.

Biasing circuit 200 further comprises a switching unit 220 that is connected to first output node Vgn and a second output node Vgn,s. Switching unit 220 is configured to output, at second output node Vgn,s and as a switched analog biasing signal, either analog biasing signal Vgn by DAC 210 or the low voltage Bn in dependence of a switching signal TDD.

FIG. 3 illustrates an implementation of biasing circuit 200. Here, DAC 210 is realized using a primary DAC 2101 and a buffer amplifier 2102. Primary DAC 2101 is configured to convert digital value Sn into an analog value irrespective of the biasing circuit it is used in. Buffer amplifier 2102 is configured to buffer the analog signal provided by primary DAC 2101. If the analog value output by primary DAC 2101 is in between low voltage Bn and high voltage An, the output of buffer amplifier 2102 will equal the analog value output by primary DAC 2101. When the analog value output by primary DAC 2101 is lower than Bn, buffer amplifier 2102 will output Bn, and when the analog value outputted by primary DAC 2101 is higher than An, buffer amplifier 2102 will output An.

Alternatively, primary DAC 2101 may have a low reference voltage V_DAC_low and a high reference voltage V_DAC_high in between which DAC 2101 outputs a voltage DAC_out. In this case, a DAC average voltage can be defined as DAC_avg=(V_DAC_high+V_DAC_low)/2. Similarly, a buffer average voltage can be defined as BUF_avg=(An+Bn)/2. In addition, a gain G of buffer amplifier 2102 can be defined using G=(An−Bn)/(V_DAC_high−V_DAC_low). Buffer amplifier 2102 can be configured to output a voltage BUF_out that equals G×(DAC_out−DAC_avg)+BUF_avg. For example, when DAC_high=5, DAC_low=−3, An=10, and Bn=−2, G would equal 12/8, DAC_avg would equal 1, and BUF_avg would equal 4. In this case, the output of buffer amplifier 2102 can be found using BUF_out=BUF_avg+G×(DAC_out−DAC_avg)=4+12/8×(DAC_out−1). It should be noted that the present disclosure may include (e.g., does not exclude) other mappings between the output voltage of DAC 2101 and the output voltage of buffer amplifier 2102.

Switching unit 220 comprises a PMOS transistor Q1 of which the source is connected to first output node Vgn and the drain to second output node Vgn,s. Its gate is connected to the output of comparator 2201, which acts as a switch controller and which will output a logical high, e.g., a voltage equal to reference voltage Vrefn, when the TDD signal is a logical high. When the TDD signal is a logical low, comparator 2201 will output Bn.

In some embodiments, Vrefn is derived from and/or equal to An. For example, biasing circuit 200 may comprise a unit for generating Vrefn based on An. In other embodiments, Vrefn is identical for each biasing circuit 200. In such case, Vrefn can be generated outside of biasing circuits 200 but on the bias control IC, or on the substrate on which the bias control IC is arranged.

Switching unit 220 further comprises an NMOS transistor Q2 of which the drain is connected to second output node Vgn,s and the source is connected to Bn.

When the TDD signal is a logical high, the voltage at the gate of Q1 is high and Q1 will be switched off. On the other hand, the gate of Q2 is high and Q2 will be switched on. Consequently, the voltage at the second output node, e.g., the switched analog biasing signal Vgn,s, will equal Bn.

When the TDD signal is a logical low, the voltage at the gate of Q1 is low and Q1 will be switched on. On the other hand, the gate of Q2 is low and Q2 will be switched off. Consequently, the voltage at the second output node, e.g., Vgn,s, will equal Vgn.

Using the TDD signal, the biasing signal at the second output node can be switched rapidly between Vgn and Bn. The signal from the second output node can therefore be used as biasing signal in TDD applications.

FIG. 4 illustrates an embodiment of a bias control integrated circuit, IC, 300 in accordance with the present disclosure. It comprises N=2 biasing circuits, that are each configured as biasing circuit 200 and that preferably are identical.

Bias control IC 300 comprises a semiconductor die 301 on which biasing circuits 200 are integrated. Each biasing circuit outputs two biasing signals. For example, biasing circuit 1 outputs a signal Vg1 and Vg1,s, whereas biasing circuit 2 outputs a signal Vg2 and Vg2,s.

Bias control IC 200 further comprises a controller 302, a temperature sensor T, a clock signal generator CLK, and an analog-to-digital converter, ADC, which converts the analog signal from temperature sensor T into a digital value and provides this signal, in dependence of the clock signal, to controller 302. Controller 302 receives a data signal D that is indicative for the biasing signals to be provided by biasing circuits 200. Controller 302 determines 2 digital values S1, S2, to be provided to the 2 biasing circuits 200, in dependence of data signal D and the digital signal provided by the ADC. This allows bias control IC 300 to output temperature dependent biasing signals for example to compensate for changes in ambient temperature. In other embodiments, a fixed biasing is used. In these embodiments, data signal D is not provided and/or controller 302 is not configured to receive such signal. Controller 302 then determines digital values S1 and S2 based solely on the measured temperature. A data interface can be provided to program controller 302 and/or the memory it comprises or is connected to.

Bias control IC 300 is configured to be arranged on a substrate. To enable connection between the circuitry on the substrate and bias control IC 300, electrical connections are to be made. In FIG. 4, these connections are indicated using thick lines 303, which each represent one or more bondwires. Furthermore, the circles indicate a node, wherein nodes with similar reference signs, e.g. A1, are electrically connected, for example using conductive traces.

The various nodes in biasing circuits 200 are connected, for example using standard routing schemes, to terminals of bias control IC 300 that are each configured to receive a voltage signal from an external source, for example, circuitry on the substrate on which bias control IC 300 is or is to be mounted. The table below indicates how the externally generated high voltages, Vh1 and Vh2, the externally generated low voltages, Vl1 and Vl2, data signal D, signal TDD, and output signals Vg1, Vg1,s, Vg2, and Vg2,s, are connected to the nodes on bias control IC 300. It is furthermore assumed that reference voltage Vref1 is generated based on voltage Vh1 and that reference voltage Vref2 is generated based on voltage Vh2.

| External | |
|---|---|
| voltage/signal | Connected to: |
| Vh1 | Connected to node A1 of biasing circuit 1 |
| Vl1 | Connected to node B1 of biasing circuit 1 |
| Vh2 | Connected to node A2 of biasing circuit 2 |
| Vl2 | Connected to node B2 of biasing circuit 2 |
| D | Connected to controller 302 |
| TDD | Connected to node TDD of biasing circuits 1, 2 |
| Vg1 | Connected to node Vg1 of biasing circuit 1 |
| Vg1, s | Connected to node Vg1, s of biasing circuit 1 |
| Vg2 (not shown) | Connected to node Vg2 of biasing circuit 1 |
| Vg2, s (not shown) | Connected to node Vg2, s of biasing circuit 1 |

FIGS. 5-7 illustrate different embodiments of a power amplifier module in accordance with the present disclosure that differ in the way the external voltages Vh1, Vl1, Vh2, and Vl2 are distributed to the 2 biasing circuits 200.

FIG. 5 illustrates a power amplifier module 500 that comprises a substrate 501 on which a bias control IC 400, a first power amplifier 10, and a second power amplifier 20 are arranged. First power amplifier 10 and second power amplifier 20 are based on different semiconductor technologies. For example, first power amplifier 10 may comprise a Silicon based LDMOS transistor and second power amplifier 20 may include a GaN based FET.

Bias control IC 400 comprises two biasing circuits 200 that can be configured similar to biasing circuits 200 in FIG. 3 or FIG. 4. Bias control IC 400 comprises a temperature sensor that outputs an analog temperature signal to controller 302. Although depicted in less detail, bias control IC 400 may comprise an ADC and clock generator as depicted in FIG. 4.

Controller 302 comprises an arithmetic unit 302A and a memory 302B. Memory 302B comprises, for each input value comprised in input signal D and for each biasing circuit, a plurality of values to be output to each biasing circuit as a function of temperature. This allows controller 302 to compensate for changes in ambient temperature.

FIG. 5 illustrates a number of terminals 502 that are shaped as pads and that are arranged on a side of substrate 501 that is opposite to the side of substrate 501 on which bias control IC 400 is mounted. Connection of terminals 502 to the opposite side of substrate 501 can be obtained using known via technology. Furthermore, bias control IC 400, power amplifier 10, and power amplifier 20, may be covered by a solidified molding compound. In this manner, an LGA type package is obtained. It should however be noted that the present disclosure is equally applicable to other packaging types.

A plurality of bondpads 503 is provided on substrate 501 on the side on which bias control IC 400 is arranged. A further plurality of bondpads 404 is provided on bias control IC 400. Some of these bondpads act as reference high node or reference low node. Bondpads 503, 404 are connected using one or more bondwires 303. It is noted that in FIG. 5 only one output node of each biasing circuit 200 is shown as being connected to power amplifier 10, 20. Furthermore, this connection is schematically shown as a line connecting the amplifier to the bondpad on substrate 501 that is connected to bias control IC 400 using a bondwire 303. Similarly, an RF input signal, RF_in, is provided to a pad on the backside of substrate. Through vias, this signal is available on the other side of substrate 501. There it is routed to the input of power amplifier 10. Again, this connection is schematically shown as a line.

The abovementioned schematically shown connections may in practice comprise bondwires, solder bumps, or other ways of electrically connecting power amplifiers 10, 20 to substrate 501. The shown connections may include more than a connection to substrate 501. For example, these connections may include vias for enabling a connection to a back side of substrate 501, and may comprise conductive traces and one or more electrical components such as surface mount devices, SMDs.

They go down to terminals 502 on the back side of the module, hence they also include vias, traces and a number of components.

In FIG. 5, each biasing circuit 200 comprises bondpads for receiving a high voltage, and a low voltage. The same TDD signal is fed to each biasing circuit, and a separate bondpad for each biasing circuit for this signal is therefore not used (e.g., required).

As shown, the bondpads of the two biasing circuits 200 are connected differently. For example, the lower biasing circuit receives values Vh2 and Vl2, whereas the upper biasing circuit receives values Vh1 and Vl1. In this embodiment, the mode the biasing circuit operates in, e.g., which low and high voltages are used, is determined by a physical connection using bondwires 303.

In FIG. 5, values Vh1, Vh2, Vl1, and Vl2 are received from one or more sources external to power amplifier module 500. Alternatively, Vh1, Vh2, Vl1, and Vl2 could be generated from other signals that may or may not have been generated on module 500 or bias control IC 400. For example, module 500 may receive voltages Va and Vb, wherein voltages Vh1 and Vh2 are generated based on voltage Va and voltages Vl1 and Vl2 are generated based on Vb. In some embodiments, Va is equal to the larger one of Vh1 and Vh2, and/or Vb is equal to the smaller one of Vl1 and Vl2.

FIGS. 6 and 7 illustrate other embodiments of a power amplifier module in accordance with the present disclosure. In FIG. 6, power amplifier module 600 comprises, as part of each biasing circuit, a reference voltage setting unit 405 that sets the high and low voltage to be used in that biasing circuit as a function of a mode signal. This mode signal may be generated by controller 302. Alternatively, it is provided external from power amplifier module 600. The mode signal indicates which mode a given biasing circuit should operate in. As illustrated in FIG. 6, reference voltage setting unit 405 is electrically connected to terminals 502 on substrate 501 that receive the various high and low voltages.

In FIG. 6, a separate and different mode signal m1, m2 is provided to each reference voltage setting unit 405. In other embodiments, the same mode signal is provided to each reference voltage setting unit 405. In this latter case, the mode signal should comprise settings for each biasing circuit and reference voltage setting unit 405 should be configured to determine which part of the mode signal is intended for which biasing circuit.

FIG. 7 illustrates an embodiment of a power amplifier module 700 in which such a shared mode signal m is used. Furthermore, in this case, a single reference voltage setting unit 405 is used that distributes the high and low voltages to be used by each biasing circuit. Furthermore, reference voltage setting unit 405 may be connected to or comprises bondpads that form common high nodes and common low nodes and that are connected using bondwires to corresponding bondpads on substrate 501.

In the embodiments discussed above, voltages Vl1, Vl2, Vh1, and Vh2 were generated external to the power amplifier module. However, these and other voltages such as mode signal m1, m2, m, can alternatively be generated on bias control IC or on substrate 501. An example thereof is shown in FIG. 8.

FIG. 8 illustrates a power amplifier module 800 in which signals Vl1, Vl2, Vh1, and Vh2 are generated by a voltage unit 405A based on externally supplied voltages Va and Vb. In addition, mode signal m is externally provided.

In the above, the present disclosure has been explained using detailed embodiments thereof. However, the present disclosure is not limited to these embodiments. Rather, various modifications are possible without departing from the scope of the present disclosure, which is defined by the appended claims and their equivalents.

What is claimed is:

1. A bias control integrated circuit for providing a plurality of biasing signals, comprising a semiconductor die on which a plurality of biasing circuits are integrated, each biasing circuit being independently operable in a mode among a plurality of modes, wherein each biasing circuit comprises:
a reference high node of which a voltage during operation is configured to be equal to a respective high voltage among a plurality of high voltages corresponding to the plurality of modes;
a reference low node of which a voltage during operation is configured to be equal to a respective low voltage among a plurality of low voltages corresponding to the plurality of modes;
an input node for receiving a digital value;
a digital-to-analog converter, DAC, for converting the received digital value into an analog biasing signal that lies in between the respective high voltage and the respective low voltage, wherein an output of the DAC forms a first output node of the biasing circuit;
a second output node; and
a switching unit connected to the first output node and second output node and configured to output, at the second output node and as a switched analog biasing signal, either the analog biasing signal output by the DAC or the respective low voltage in dependence of a switching signal.

2. The bias control integrated circuit according to claim 1, wherein a polarity of at least one high voltage is different from the polarity of at least one other high voltage or wherein a polarity of at least one low voltage is different from the polarity of at least one other low voltage.

3. The bias control integrated circuit according to claim 1, wherein the switching unit of each biasing circuit comprises:
a first switching unit arranged in between the first output node and the second output node of the biasing circuit;
a second switching unit arranged in between the second output node and a reference node that is electrically connected to the reference low node; and
a switch controller configured for controlling the first switching unit and the second switching unit in dependence of the switching signal;
wherein the switch controller is configured to control, in response to the switching signal having a first logical value, the first switching unit to provide a low ohmic connection between the first output node and the second output node, and the second switching unit to provide a high ohmic connection between the second output node and the reference node; and
wherein the switch controller is configured to control, in response to the switching signal having a second logical value different from the first logical value, the first switching unit to provide a high ohmic connection between the first output node and the second output node, and the second switching unit to provide a low ohmic connection between the second output node and the reference node.

4. The bias control integrated circuit according to claim 1, wherein the plurality of modes comprise:
a first mode in which the voltage at the reference high node during operation is configured to be equal to a first high voltage and the voltage at the reference low node during operation is configured to be equal to a first low voltage; and
a second mode during which the voltage at the reference high node during operation is configured to be equal to a second high voltage and the voltage at the reference low node during operation is configured to be equal to a second low voltage.

5. The bias control integrated circuit according to claim 1, wherein the reference high node and reference low node of each biasing circuit among the plurality of biasing circuits are each formed by a terminal, and wherein, for the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage or the supply of the low voltage are arranged off the semiconductor die.

6. The bias control integrated circuit according to claim 1, comprising a reference voltage setting unit configured to set, in dependence of a mode signal for a given biasing circuit intended for setting that biasing circuit to operate in a given mode among the plurality of modes:
the voltage at the reference high node of that biasing circuit to a high voltage among the plurality of high voltages that corresponds to the given mode; and
the voltage at the reference low node of that biasing circuit to a low voltage among the plurality of low voltages that corresponds to the given mode.

7. The bias control integrated circuit according to claim 6, wherein the semiconductor die comprises:
a plurality of common high nodes of which the voltages during operation equal the plurality of high voltages;
a plurality of common low nodes of which the voltages during operation equal the plurality of low voltages;
wherein the reference voltage setting unit is connected to the plurality of common high nodes and to the plurality of common low nodes.

8. The bias control integrated circuit according to claim 7,
wherein the common high nodes of the plurality of common high nodes are configured to be electrically connected to supplies of the high voltages; or
wherein the common low nodes of the plurality of common low nodes are configured to be electrically connected to supplies of the low voltages;
wherein the supplies of the high voltages or the supplies of the low voltages are arranged off the semiconductor die; and
wherein the reference voltage setting unit is configured to set each biasing circuit among the plurality of biasing circuits to operate in a given mode among the plurality of modes in dependence of a mode signal that indicates a desired mode for each of the biasing circuits.

9. The bias control integrated circuit according to claim 1, wherein the semiconductor die comprises a controller that is configured for determining and providing a respective digital value for each biasing circuit, wherein the controller is configured for receiving one or more input signals and for determining the respective digital values in dependence of the one or more input signals, wherein the controller is configured for receiving a separate input signal for each biasing circuit.

10. The bias control integrated circuit according to claim 9, wherein the controller is configured for generating the respective digital value for each biasing circuit in dependence of a temperature measured by a temperature sensor and the one or more input signals.

11. The bias control integrated circuit according to claim 10, wherein the temperature sensor is arranged on the semiconductor die.

12. The bias control integrated circuit according to claim 10, wherein the controller comprises:
a lookup table holding a respective digital value for a plurality of temperatures and a plurality of possible values of the one or more input signals; and
an arithmetic unit configured to calculate or determine the digital value to be outputted to each biasing circuit based on the measured temperature, the digital value or values held in the lookup table that correspond to the measured temperature for the values of the one or more input signals.

13. The bias control integrated circuit according to claim 12, wherein the arithmetic unit is configured to determine the digital value to be outputted to each biasing circuit using interpolation based on two or more digital values held in the lookup table that correspond to temperatures that are higher and lower than the measured temperature, wherein the lookup table holds respective digital values for a plurality of temperatures for each biasing circuit separately.

14. An RF power amplifier module, comprising:
a plurality of power amplifiers, each power amplifier having one or more power transistors of a technology that is different from the technology of the power transistors of at least one other power amplifier among the plurality of power amplifiers;
a bias control integrated circuit for providing a plurality of biasing signals, comprising a semiconductor die on which a plurality of biasing circuits are integrated, each biasing circuit being independently operable in a mode among a plurality of modes, wherein each biasing circuit comprises:
a reference high node of which a voltage during operation is configured to be equal to a respective high voltage among a plurality of high voltages corresponding to the plurality of modes;
a reference low node of which a voltage during operation is configured to be equal to a respective low voltage among a plurality of low voltages corresponding to the plurality of modes;
an input node for receiving a digital value;
a digital-to-analog converter, DAC, for converting the received digital value into an analog biasing signal that lies in between the respective high voltage and the respective low voltage, wherein an output of the DAC forms a first output node of the biasing circuit;
a second output node; and
a switching unit connected to the first output node and second output node and configured to output, at the second output node and as a switched analog biasing signal, either the analog biasing signal output by the DAC or the respective low voltage in dependence of a switching signal;
wherein each biasing circuit is configured to provide its analog biasing signal or its switched analog biasing signal to a controlling input of a respective power transistor of a power amplifier among the plurality of power amplifiers;
wherein the biasing circuit of the bias control integrated circuit that is configured to bias the power transistor of a given power amplifier among the plurality of power amplifiers are configured to operate in a different mode than the biasing circuit of the bias control integrated circuit that is configured to bias the power transistor of a different power amplifier among the plurality of power amplifiers.

15. The power amplifier module according to claim 14, wherein the one or more power transistors of a power amplifier among the plurality of power amplifiers are based on a same semiconductor material that is different from a semiconductor material on which the one or more power transistors of a different power amplifier among the plurality of power amplifiers are based;
wherein the one or more power transistors of a first power amplifier among the plurality of power amplifiers are based on Gallium Nitride, and for example each comprise a Gallium Nitride based field-effect transistor, and the one or more power transistors of a second power amplifier among the plurality of power amplifiers are based on Silicon, and for example each comprise a Silicon laterally diffused metal-oxide-semiconductor transistor.

16. The power amplifier module according to claim 14, further comprising a first substrate, such as a laminate substrate, wherein the one or more power transistors of each power amplifier are provided as one or more semiconductor dies mounted on the first substrate;
wherein the first substrate comprises one or more terminals for electrically connecting the power amplifier module to a second substrate on which the power amplifier module is or is to be mounted;
wherein the power amplifier module is packaged as a land grid array, LGA, package, or a no-lead package, such as a quad flat no-lead package, QFN.

17. The power amplifier module according to claim 16, wherein the reference high node and reference low node of each biasing circuit among the plurality of biasing circuits are each formed by a terminal, and wherein, for the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage or the supply of the low voltage are arranged off the semiconductor die, wherein the off-die supplies for the high voltages of the plurality of high voltages and wherein the off-die supplies for the low voltages of the plurality of low voltages are realized using one or more voltage generating units arranged on the first substrate.

18. The power amplifier module according to claim 16, wherein the reference high node and reference low node of each biasing circuit among the plurality of biasing circuits are each formed by a terminal, and wherein, for the purpose of operating a given biasing circuit in a respective mode, the reference high node and reference low node of that biasing circuit are configured to be connected a supply of the high voltage and to a supply of the low voltage that correspond to the mode that biasing circuit operates or should operate in, respectively, wherein the supply of the high voltage or the supply of the low voltage are arranged off the semiconductor die, the power amplifier module comprising a plurality of terminals configured to be connected to supplies of the high voltages and to supplies of the low voltages external to the power amplifier module, wherein the reference high node and reference low node of each biasing circuit are electrically connected to a respective terminal among the plurality of terminals of the power amplifier module.

19. A biasing control integrated circuit, comprising:
a biasing circuit, comprising:
a reference high node of which a voltage during operation is configured to be equal to a respective high voltage among a plurality of high voltages corresponding to a plurality of modes;
a reference low node of which a voltage during operation is configured to be equal to a respective low voltage among a plurality of low voltages corresponding to the plurality of modes;
an input node for receiving a digital value;
a digital-to-analog converter, DAC, for converting the received digital value into an analog biasing signal that lies in between the respective high voltage and the respective low voltage, wherein an output of the DAC forms a first output node of the biasing circuit;
a second output node; and
a switching unit connected to the first output node and second output node and configured to output, at the second output node and as a switched analog biasing signal, either the analog biasing signal output by the DAC or the respective low voltage in dependence of a switching signal; and
a reference voltage setting unit configured to set, in dependence of a mode signal for the biasing circuit intended for setting the biasing circuit to operate in a given mode among the plurality of modes:
the voltage at the reference high node of the biasing circuit to a high voltage among the plurality of high voltages that corresponds to the given mode; and
the voltage at the reference low node of the biasing circuit to a low voltage among the plurality of low voltages that corresponds to the given mode;
wherein a polarity of at least one high voltage is different from the polarity of at least one other high voltage or wherein a polarity of at least one low voltage is different from the polarity of at least one other low voltage.

20. A biasing control integrated circuit, comprising:
a biasing circuit, comprising:
a reference high node of which a voltage during operation is configured to be equal to a respective high voltage among a plurality of high voltages corresponding to a plurality of modes;
a reference low node of which a voltage during operation is configured to be equal to a respective low voltage among a plurality of low voltages corresponding to the plurality of modes;
an input node for receiving a digital value;
a digital-to-analog converter, DAC, for converting the received digital value into an analog biasing signal that lies in between the respective high voltage and the respective low voltage, wherein an output of the DAC forms a first output node of the biasing circuit;
a second output node; and
a switching unit connected to the first output node and second output node and configured to output, at the second output node and as a switched analog biasing signal, either the analog biasing signal output by the DAC or the respective low voltage in dependence of a switching signal; and
wherein the reference high node and reference low node of the biasing circuit are each formed by a terminal, and wherein, for the purpose of operating the biasing circuit in a respective mode, the reference high node and reference low node of the biasing circuit are configured to be connected a supply of the high voltage and to a supply of the low voltage that correspond to the mode the biasing circuit operates or should operate in, respectively;
wherein a polarity of at least one high voltage is different from the polarity of at least one other high voltage or wherein a polarity of at least one low voltage is different from the polarity of at least one other low voltage.
